(19) United States
(12) Patent Application Publication
(10) Pub. No.: US 2012/0181166 A1
(43) Pub. Date: Jul. 19, 2012

(54) PVD PROCESS WITH SYNCHRONIZED PROCESS PARAMETERS AND MAGNET POSITION

(75) Inventors: QIAN LUO, Union City, CA (US); Ye Xu, Sunnyvale, CA (US); Tza-Jing Gung, San Jose, CA (US); Xianmin Tang, San Jose, CA (US)

(73) Assignee: APPLIED MATERIALS, INC., Santa Clara, CA (US)

(21) Appl. No.: 13/007,228

(22) Filed: Jan. 14, 2011

(51) Int. Cl. C23C 14/35

(52) U.S. Cl. 204/192.12

(57) ABSTRACT

Embodiments of the present invention generally relate to methods for physical vapor deposition processes. The methods generally include synchronizing process chamber conditions with the position of a magnetron. As the magnetron is scanned over a first area of a target, the conditions within the chamber are adjusted to a first set of predetermined process conditions. As the magnetron is subsequently scanned over a second area of the target, the conditions within the chamber are adjusted to a second set of predetermined process conditions different the first set. The target may be divided into more than two areas. By correlating the position of the magnetron with different sets of process conditions, film uniformity can be improved by reducing center-to-edge non-uniformities, such as re-sputter rates which may be higher when the magnetron is near the edge of the target.

### BACKGROUND OF THE INVENTION

1. Field of the Invention

Embodiments of the present invention generally relate to controlling processing conditions during physical vapor deposition processes.

2. Description of the Related Art

Physical vapor deposition (PVD), alternatively called sputtering, is a process for depositing metals and related materials during the fabrication of semiconductor integrated circuits. PVD use has been extended to depositing metal layers onto the sidewalls of high aspect-ratio holes such as vias or other vertical interconnect structures. Current sputtering applications include depositing a copper seed layer in a via for later electroplating copper, and depositing a barrier layer on the dielectric material of the via sidewall to prevent the copper from diffusing into the dielectric.

Plasma sputtering typically includes a magnet positioned at the back of a sputtering target to project a magnetic field into the processing space to increase the density of the plasma and enhance the sputtering rate. Typically, the magnet is rotated or scanned across the target to provide a more uniform erosion pattern of the target and a more uniform deposition profile on a substrate. However, as the magnet is rotated or scanned across the target surface, the magnetic fields interacting with plasma within a process chamber also move. Thus, process conditions within the process chamber constantly change as the magnet changes position. The changing process conditions ultimately affect deposition uniformity on the substrate.

Therefore, there is a need for a PVD process in which process parameters are synchronized with the position of the magnet.

### SUMMARY OF THE INVENTION

Embodiments of the present invention generally relate to methods for PVD processes. The methods generally include synchronizing process chamber conditions with the position of a magnetron. As the magnetron is scanned over a first area of a target, the conditions within the chamber are adjusted to a first set of predetermined process conditions. As the magnetron is subsequently scanned over a second area of the target, the conditions within the chamber are adjusted to a second set of predetermined process conditions different the first set. The target may be divided into more than two areas. By correlating the position of the magnetron with different sets of process conditions, film uniformity can be improved by reducing center-to-edge non-uniformities, such as re-sputter rates which may be higher when the magnetron is near the edge of the target.

In one embodiment, a PVD method comprises scanning a magnetron over a first area of a target and sputtering a material from the target to a substrate while biasing the substrate with a first bias. The method also comprises scanning the magnetron over a second area of the target and sputtering the material from the target to the substrate while biasing the substrate with a second bias different than the first bias.

In another embodiment, a PVD method comprises scanning a magnetron over a first area of a target and sputtering a material from the target to a substrate under a first set of processing conditions. The method also comprises scanning the magnetron over a second area of the target and sputtering the material from the target to the substrate under a second set of processing conditions different than the first set of processing conditions.

In another embodiment, a PVD method comprises positioning a substrate adjacent to a target in a processing chamber, and igniting a plasma in a processing region located within the processing chamber. Process conditions within the processing chamber are adjusted to a first set of predetermined processing conditions, and a magnetron is scanned over a first area of the target to sputter material from the target to the substrate. The processing conditions within the processing chamber are then adjusted to a second set of predetermined processing conditions different than the first set of predetermined processing conditions, and the magnetron is scanned over a second area of the target to sputter material from the target to the substrate. The processing conditions within the processing chamber are then adjusted to a third set of predetermined processing conditions different than the first set and the second set of predetermined processing conditions, and the magnetron is scanned over a third area of the target to sputter material from the target to the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of a processing chamber according to one embodiment of the invention.

FIGS. 2A-2B are schematic illustrations of target scanning patterns.

FIG. 2C is a graph illustrating the rate of re-sputter at multiple locations on a substrate for multiple magnetron scan path radii.

FIG. 3 is a flow chart illustrating one embodiment of the invention.

FIG. 4 is chart illustrating the rate of re-sputter across a substrate surface using the scan path of FIG. 2B.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to methods for PVD processes. The methods generally include synchronizing process chamber conditions with the position of a magnetron. As the magnetron is scanned over a first area of a target, the conditions within the chamber are adjusted to a first set of predetermined process conditions. As the magnetron is subsequently scanned over a second area of the target, the conditions within the chamber are adjusted to a second set of predetermined process conditions different the first set. The target may be divided into more than two areas. By correlating the position of the magnetron with different sets of process conditions, film uniformity can be improved by reducing center-to-edge non-uniformities, such as re-sputter rates which may be higher when the magnetron is near the edge of the target.

Embodiments described herein may be practiced in the ENCORE™ II RFX Cu chamber available from Applied Materials, Inc., of Santa Clara, Calif. It is to be understood that the invention may have utility in other systems, including those sold by other manufacturers.

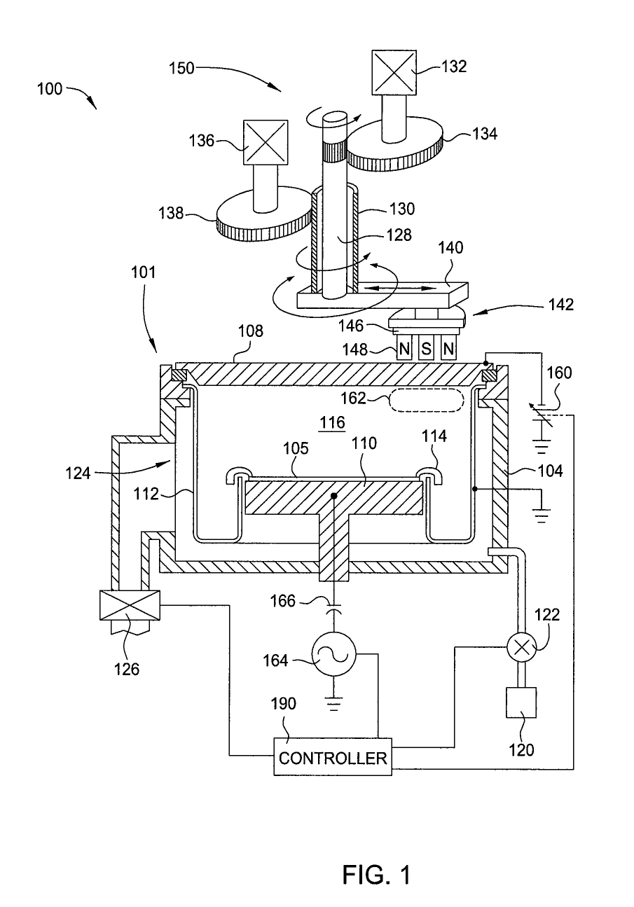

FIG. 1 is a schematic illustration of a processing chamber 100 according to one embodiment of the invention. The processing chamber 100 includes a chamber body 101, a magnetron assembly 150, and a controller 190. The chamber body 101 includes sidewalls 104. A target 108 is positioned on the chamber body 101 and encloses a processing region 116. The chamber body 101 is fabricated from welded plates of stainless steel, but may also be formed from a unitary block of aluminum. The sidewalls 104 include a slit valve (not shown) to provide for entry and egress of a substrate 105 from the processing chamber 100. A substrate support 110 is positioned within a lower portion of the processing chamber 100 opposite the target 108. A grounded shield 112 encircles the substrate support 110 and prevents deposition of sputtered material on the sidewalls 104. A clamp ring 114 may be used to hold the substrate 105 to the substrate support 110 or to protect the periphery of the substrate support 110 from deposition.

The substrate support 110 supports the substrate 105 during processing. The substrate support 110 is an electrostatic chuck, but may alternatively be a ceramic body, a heater, or a combination thereof. The substrate support 110 is formed from aluminum; however, it is contemplated that the substrate support 110 may be formed from other materials, including ceramic. The substrate support 110 has a substrate receiving surface that receives and supports the substrate 105 during processing. The substrate receiving surface is generally parallel to the lower surface of the target 108.

A gas source 120 is coupled to the chamber body 101 to provide a process gas to the processing region 116. A valve 122 is positioned between the gas source 120 and the processing region 116 to control the gas flow rate to the processing region 116. Process gas is removed from the chamber body 101 through a pumping port 124 by an exhaust pump 126. The process gas may be an inert gas, such as argon or xenon, or may be a reactive gas, such as oxygen or nitrogen.

A magnetron assembly 150 is positioned above the target 108. The magnetron assembly 150 includes an inner rotary shaft 128 and a tubular outer rotary shaft 130, which are coaxial and are arranged about and extend along the central axis. A first motor 132 is coupled to the inner rotary shaft 128 by a drive gear 134. A second motor 136 is similarly coupled to the outer rotary shaft 130 through another drive gear 138. The shafts 128 and 130 are coupled to a magnetron support 140 which supports a magnetron 142 and scans the magnetron 142 over the back of the target 108 during processing. The magnetron 142 includes a magnetic yoke 146 and magnets 148. The magnets 148 may be electromagnets which may be biased during processing. Although the magnetron assembly 150 is described herein as having a rotary scanning path, it is contemplated that other magnetron assemblies having other scanning patterns may also be used.

The chamber 100 is controlled by a system controller 190 that is generally designed to facilitate the control and automation of the processing chamber 100 and typically includes a central processing unit (CPU), memory, and support circuits. The CPU may be one of any form of computer processors that are used in industrial settings for controlling various system functions, magnetron movement, chamber processes, and support hardware (e.g., sensors, robots, motors, etc.), and monitor the processes (e.g., substrate support temperature, power supply variables, chamber process time, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 190 determines which tasks are performable on a substrate. Preferably, the program is software readable by the system controller 190 that includes code to perform tasks relating to monitoring, execution and control of the movement and various process recipe tasks and recipe steps being performed in the processing chamber 100. For example, the controller 190 can comprise program code that synchronizes process parameters within the chamber 100 with the position of the magnetron 142.

During processing, a DC power supply 160 negatively biases the target 108 with respect to the grounded shield 112 and causes processing gas within the processing region 116 to be excited and discharge into a plasma. The magnetron 142 concentrates the plasma and creates a high density plasma (HDP) region 162 underneath the magnetron 142 inside the processing region 116. The positively charged processing gas ions are attracted to the target 108 with sufficient energy to sputter material from the target 108. The sputtered material deposits on and coats the substrate 105 positioned on the substrate support 110. An RF power supply 164 is connected to the substrate support 110 through a capacitive coupling circuit 166 to create a negative bias on the substrate 105. The bias accelerates positive ions towards the substrate 105 in trajectories which allow for effective high aspect ratio coverage.

Due to the high energy imparted on the ions by the bias of the RF power supply 164, the accelerated ions may also re-sputter material deposited on the substrate 105. As the magnetron 142 scans across the surface of the target 108, the HDP region 162 also scans across the target 108. The moving HDP region 162 affects the trajectory and speed at which sputtered material contacts the substrate 105, and therefore the rate at which deposited material is re-sputtered. The varying re-sputtering rate often results in a higher re-sputtering rate near the edge of the substrate 105 as compared to a central portion of the substrate 105.

Since the re-sputter rate of material is greater near the edge of the substrate 105, a center-to-edge non-uniformity is generated. Thus, it is desirable to either reduce the re-sputter rate near the edge of the substrate or increase the re-sputter rate near the center of the substrate 105 to correct the non-uniformity. This can be accomplished by adjusting the process conditions within the chamber 100, or adjusting the position of the magnetron scan path. However, adjusting the position of the magnetron scan path will affect (and likely decrease) target erosion uniformity. Re-sputter rates can most efficiently be changed (without affecting target erosion uniformity or profile) by changing the process conditions or process parameters in the processing chamber 100. Although a change in process conditions will generally affect re-sputter rates, the process conditions for the entire process cannot simply be changed or scaled as a whole, because the center-to-edge non-uniformity will remain. This is due to the fact that the magnetron 142 still causes re-sputtering across the entire surface of the substrate regardless of the magnetron position (although the re-sputtering rate will vary depending on the magnetron 142 position during processing). For example, when the magnetron 142 is positioned near the edge of the target 108, re-sputter will occur near the center of the substrate and near the edge of the substrate, but at a higher rate near the edge of the substrate. Conversely, when the magnetron 142 is near the center of the target 108, re-sputter will occur near the center of the substrate and near the edge of the substrate, but at a higher rate near the center of the substrate. Thus, in order to account for center-to-edge non-uniformities, a process consisting of multiple sub-steps synchronized with magnetron position can be used. Each sub-step can correspond to a defined magnetron position, and each sub-step can be designed to compensate for the center-to-edge non-uniformities when the magnetron 142 is in the defined position.

In order to cause uniform re-sputter across the substrate 105, a first set of process conditions (e.g., a first sub-step) may be used when the magnetron 142 is positioned near the edge of the target 108, and a second set of process conditions (e.g., a second sub-step) may be used when the magnetron 142 is positioned near the center of the target 108. The first and second set of process conditions can be tailored to compensate for undesired center-to-edge deposition effects, such as uneven re-sputtering. By effecting an even rate of re-sputter across the surface of substrate 105, a more uniform material deposition can be accomplished, and process uniformity can be more tightly controlled.

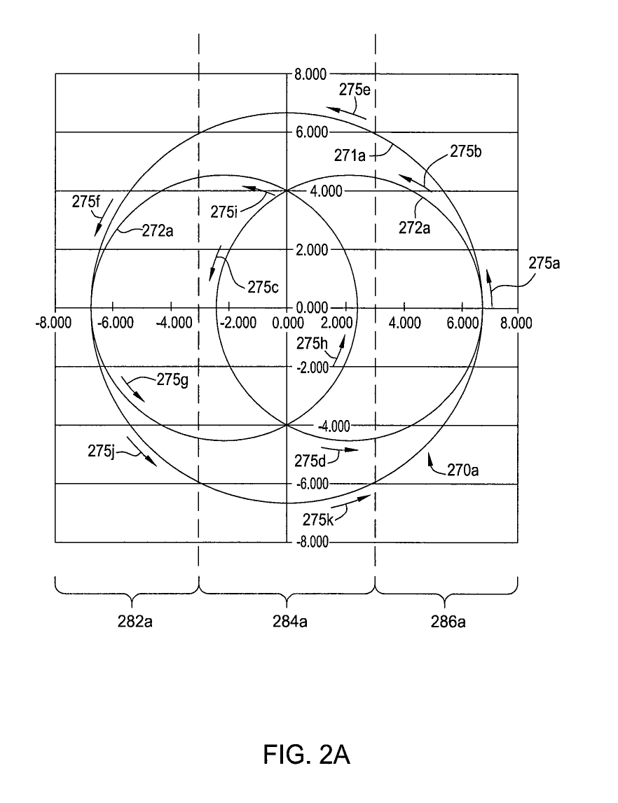

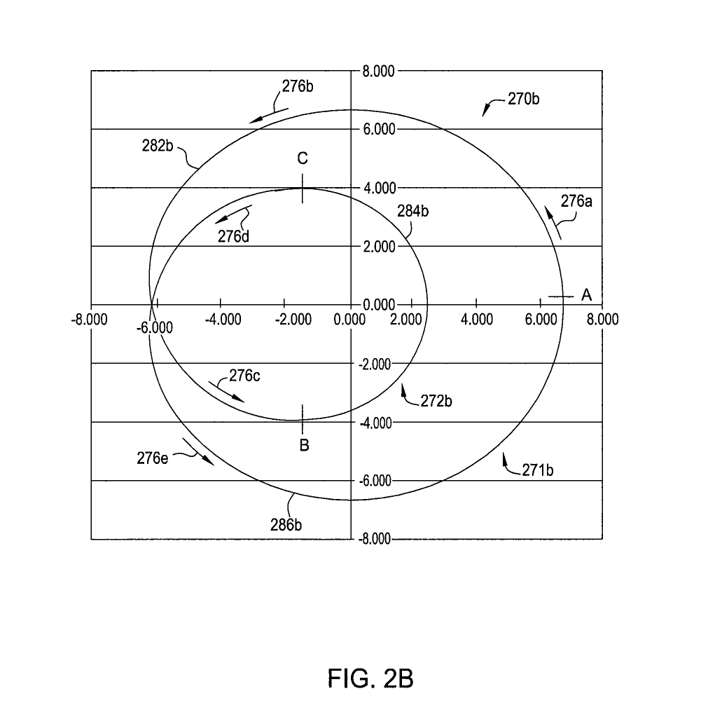

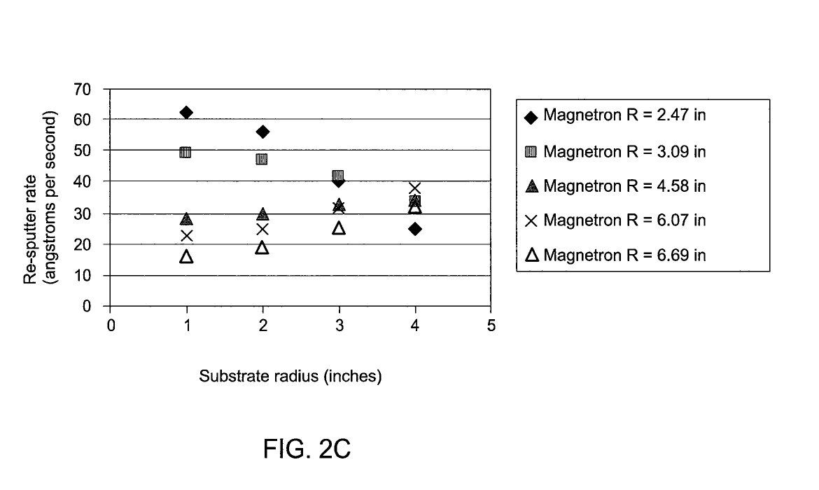

FIGS. 2A-2B are schematic illustrations of target scanning patterns. FIG. 2A illustrates a magnetron scan path 270a which is used to scan a target and sputter material to a substrate. The target is generally a circular target having a radius of about 8 inches; however, the scan path 270a is shown on a rectangular system (having units of inches) for purposes of explaining the scan path 270a. It is contemplated that scan path 270a may be applicable to targets of other sizes and shapes, such as rectangular targets.

The magnetron scan path 270a includes a first circular path 271a near the outer edge of a target, and two smaller circular paths 272a passing near the center of the target. The magnetron follows the scan path 270a as dictated by arrows 275a-275k, and is generally centered over the lines of the scan path 270a during sputtering to maximize target erosion uniformity. The magnetron 142 begins scanning at arrow 275a and scans around a first smaller circular path 272a as indicated by arrows 275b-275d, and returning to arrow 275a. From arrow 275a, the magnetron 142 scans along the first circular path 271a as indicated by arrows 275e and 275f. At arrow 275f, the magnetron 142 enters the second smaller circular path 272b and scans as indicated by arrows 275g-275i. After completing one revolution of the second smaller circular path 272a, the magnetron 142 continues scanning along the first circular path 271a as indicated by arrows 275j and 275k. The magnetron returns to arrow 275a which completes one scanning revolution.

As the magnetron scans across the target 108, the substrate 105 will be subjected to a radially-increasing higher re-sputter rate across the surface of the substrate, thus causing a center-to-edge film non-uniformity. To compensate for the difference in re-sputter rate across the surface of the substrate, a first set of process conditions are used when the magnetron 142 is in areas 282a and 286a (near the left and right edges of the target), and a second set of process conditions are used when the magnetron 142 is in area 284a (near the center of the target). Therefore, as the magnetron 142 travels along the magnetron scan path 270a during processing, the magnetron 142 will go in and out of areas 282a, 284a, and 286a multiple times, each time adjusting process conditions as instructed by the controller 190. The adjusted process conditions are selected to compensate for the difference in re-sputter rates caused by the changing magnetron position with respect to the center of the target.

The areas 282a, 284a, and 286a are divided such that the area 284a covers about 40 percent of the surface area of the target, while each of areas 282a and 286a cover about 30 percent of the target. However, it is contemplated that the areas 282a, 284a, and 286a may cover other proportional surface areas of target. For example, areas 282a, 284a, and 286a may be divided to cover 25 percent, 50 percent, and 25 percent, respectively. Alternatively, areas 282a, 284a, and 286a may be divided to cover 20 percent, 60 percent, and 20 percent, respectively. Furthermore, although FIG. 2A is shown as having three areas 282a, 284a, and 286a , it is contemplated that the target 108 can be divided into as few as two areas, or into more than three areas. For example, the target may be divided into 5, 9, 15, or more areas. Additionally, it is contemplated that the areas 282a, 284a, and 286a may be formed into various other shapes. For example, 282, 284, and 286 may be concentrically positioned around one another. Also, it is contemplated that the areas 282a, 284a, and 286a may be of equal sizes and the magnetron scanning rate may be varied as the magnetron 142 scans through each of the areas 282a, 284a, and 286a.

As the magnetron 142 scans from one area of the target to another area of the target, one or more process conditions are adjusted by the controller 190. The process conditions which may be adjusted include, but are not limited to substrate support bias, target bias, electromagnet bias, process gas flow, and magnetron scanning rate, among other process parameters. For example, if it is desirable to reduce re-sputtering of deposited material, areas 282a and 286a may correspond to a process recipe having a substrate bias lower than the substrate bias of a process recipe corresponding to area 284a. Additionally, although areas 282a and 286a are described as having the same process conditions during processing, it is contemplated that all of the areas of the target may correspond to different sets of process conditions.

FIG. 2B illustrates a magnetron scan path 270b which is used to scan a target and sputter material to a substrate. The target is generally a circular target having a radius of about 8 inches; however, the scan path 270b is shown on a rectangular system (having units of inches) for purposes of explaining the scan path 270b. It is contemplated that scan path 270b may be applicable to targets of other sizes and shapes, such as rectangular targets.

The scan path 270b includes a first circular path 271b and small, non-concentric circular path 272b. The target is divided into three areas 282b, 284b, and 286b, with each area 282b, 284b, and 286b corresponding to a portion of the magnetron scan path 270b. The area 282b corresponds to portion of the magnetron scan path 270b between point A and point B. The area 284b corresponds to the portion of the magnetron scan path 270b between point B and point C. The area 286b corresponds to the portion of the magnetron scan path 270b between point C and point A. Thus, the target can be divided into different areas based on the scan path 270b, as opposed to dividing the surface area of the target as a whole into desired fractions (as shown in FIG. 2A).

The magnetron 142 is generally centered on the line of the magnetron scan path 270b during processing. The magnetron 142 is scanned along the scan path 270b in a direction indicated by arrows 276a -276e. Beginning at point A, the magnetron is scanned along the first circular path 271b along as indicated by arrows 276a-276a to point B (entering the smaller circular path 272b). The magnetron is then scanned from point B to point C within the smaller circular path 272b. From point C, the magnetron 142 exits the smaller circular path 272b and scans along the first circular path 271b as indicated by arrows 276d and 276e, finally returning to point A.

The position of points A, B, and C will vary in each system depending on target bias, magnet strength, scan path, etc. The positions of points A, B, and C for a given system are chosen such that the re-sputter ratio near the edge of the substrate is approximately equal to the re-sputter rate near the center of the substrate during a sputtering processing. The points A, B, and C are selected based on experimental results using a simplified magnetron scan path shaped as a single circle, and then translating points A, B, and C to the desired process scan path (for example, magnetron scan path 270b). Desirably, the re-sputter rate near the edge of the substrate is equal to the re-sputter rate near the center of the substrate, as stated by Equation 1.

ΣR_{c-in}tᵢₙ+ΣR_{c-out}tₒᵤₜ=ΣRₑ₋ᵢₙtᵢₙ+ΣRₑ₋ₒᵤₜtₒᵤₜ (Equation 1)

R_{c-in} is the rate of re-sputter near the center of the substrate when magnetron is positioned near the center of the target. R_{c-out} is the rate of re-sputter near the center of the substrate when magnetron is positioned near the edge of the target. Rₑ₋ᵢₙ is rate of re-sputter near the edge of the substrate when magnetron is positioned near the center of the target. Rₑ₋ₒᵤₜ is the rate of re-sputter near the edge of the substrate when magnetron is positioned near the edge of the target. It is necessary to account for the re-sputter rate at both the center and the edge of the substrate regardless of the magnetron position since re-sputter will occur in both places; however, the rate of re-sputter is generally greater on the area substrate proximate to the magnetron position (e.g., the rate or re-sputter will be greater along the edge of the substrate when the magnetron is near the edge of the target). Tᵢₙ is the amount of time the magnetron scans the inner portion of the target (e.g., between point and point B). Tₒᵤₜ is the amount of time the magnetron scans the outer portion of the target (e.g., between point A to point B and between Point C to Point A). Thus, Equation 1 accounts for a change in magnetron scan rate.

As explained above, substrate support bias directly affects the rate of re-sputter on the substrate. Thus, Equation 1 can be modified to account for the bias of the substrate support to yield Equation 2.

ΣR_{c-in}tᵢₙBᵢₙ+ΣR_{c-out}tₒᵤₜBₒᵤₜ=ΣRₑ₋ᵢₙtᵢₙBᵢₙ+ΣRₑ₋ₒᵤₜtₒᵤₜBₒᵤₜ (Equation 2)

Bᵢₙ is the bias applied to the substrate support when the magnetron is scanned near the center of the target (the path along point B to point C), and Bₒᵤₜ is the bias applied to the substrate support when the magnetron is scanned near the edge of the target (the paths between point A and B, and between point C and point A). If it is desirable to change another process parameter instead of or in addition to the substrate support bias, the desired process parameter would be substituted for Bᵢₙ and Bₒᵤₜ.

Equation 2 can be simplified using the average re-sputter rates and magnetron scan times. Equation 2 can then be rearranged to form Equation 3.

(R_{c-in}−Rₑ₋ᵢₙ)tᵢₙBᵢₙ=(Rₑ₋ₒᵤₜ−R_{c-out})tₒᵤₜBₒᵤₜ (Equation 3)

Generally, the average re-sputter rates (R_{c-in}, Rₑ₋ᵢₙ, Rₑ₋ₒᵤₜ, and R_{c-out}) are experimentally determined. To determine R_{c-in}, Rₑ₋ᵢₙ, Rₑ₋ₒᵤₜ, and R_{c-out}, a magnetron is scanned over a target at varying radii to determine the distance at which the re-sputter rate near the center of the substrate is equal to the re-sputter rate near the edge of the substrate.

FIG. 2C is a graph illustrating the rate of re-sputter at multiple locations on a substrate having a four inch radius for multiple magnetron scan path radii. As can be seen from FIG. 2C, the magnetron scan radius at which the re-sputter rate near the edge of a substrate is equal to the re-sputter rate near the center of the substrate is between 3.09 inches and 4.58 inches, for example, about four inches. Thus, the transition from an “inner area” of the target to an “outer area” of the target occurs at about four inches for the given process parameters. Therefore, in a magnetron scanning profile such as scan path 270b, point B and point C would be at about 4 inches from the center of target 108. Point A is generally positioned along the scan path at a position closest to the target edge.

Returning to FIG. 2B, once having determined points A, B, and, C, a second set of experimental values are determined for R_{c-in}, Rₑ₋ᵢₙ, Rₑ₋ₒᵤₜ, and Rₑ₋ₒᵤₜ using points A, B, and C. For the second set of experimental values, R_{c-in} corresponds to the average re-sputter rate at the center of the substrate when the magnetron is at point B or point C, and Rₑ₋ᵢₙ corresponds to the average re-sputter rate at the edge of the substrate when the magnetron is at point B or point C. Rₑ₋ₒᵤₜ corresponds to the average re-sputter rate at the edge of the substrate when the magnetron is at point A, and Rₑ₋ₒᵤₜ corresponds to the average re-sputter rate at the center of the substrate when the magnetron is at point A. The ratio of (R_{c-in}−Rₑ₋ᵢₙ)/(Rₑ₋ₒᵤₜ−R_{c-out})=Bᵢₙ/Bₒᵤₜ. Thus, during processing, if a substrate support bias of 1200 watts was applied while the magnetron was positioned near the center of the target, a substrate support bias of 1200 watts * (Bᵢₙ/Bₒᵤₜ) would be applied when the magnetron was positioned near the edge of the target. Finally, since R_{c-in}, Rₑ₋ᵢₙ, Rₑ₋ₒᵤₜ, R_{c-out}, Bᵢₙ, and Bₒᵤₜ have been determined, the ratio of tᵢₙ and tₒᵤₜ can be determined using Equation 3 above. The values tᵢₙ and tₒᵤₜ determine the amount of time the magnetron scans near the center of the target and the edge of the target along the respective portion of the scanning path. Thus, the magnetron scanning rate is variable during processing, and further, the target 108 of FIG. 2B is divided into areas which each area having a different magnetron dwell time. It is to be noted, however, that any of the variables determined above can be adjusted to further increase film uniformity.

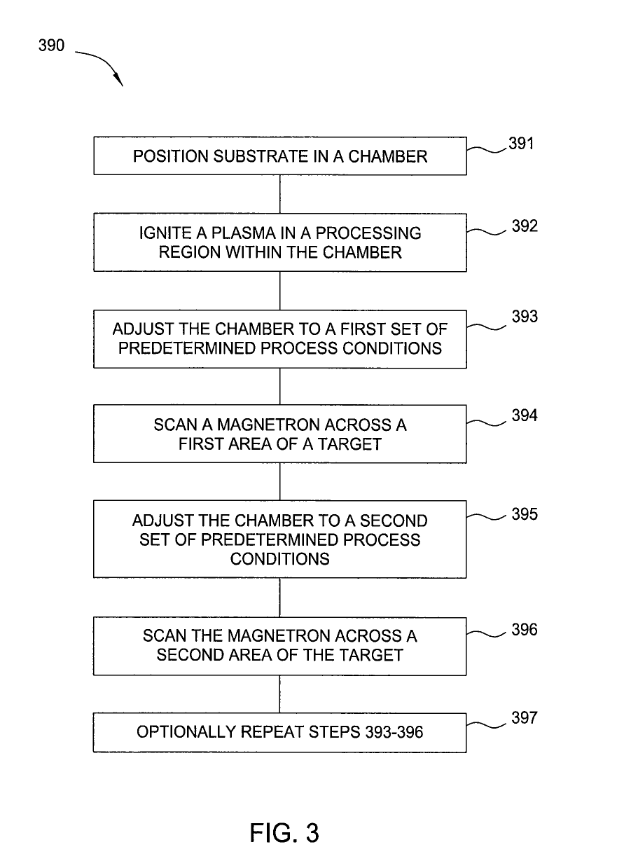

FIG. 3 is a flow chart illustrating one embodiment of the invention. The flow chart 390 illustrates steps 391 through 397 for processing a substrate in a processing chamber in which the magnetron has been synchronized with a target having two areas. In step 391, a substrate is positioned on a substrate support within the process chamber. In step 392, a plasma is ignited to the processing region of the process chamber. The plasma may be generated in situ or may provided to the processing region by a remote plasma source. In step 393, the process conditions within the process chamber are adjusted to a first set of predetermined process conditions. The first set of predetermined process conditions may include substrate support bias, target bias, electromagnet bias, process gas flow rate, process chamber pressure, substrate temperature, and magnetron scan rate.

In step 394, a magnetron is scanned over a first area of a target corresponding to the first set of predetermined process conditions. During step 394, a material is deposited on a substrate positioned within the processing chamber. In step 395, as the magnetron exits the first area, a controller adjusts the process conditions within the processing chamber to a second set of predetermined process conditions. The second set of predetermined process conditions has at least one process parameter which is different than the first set of predetermined process conditions. In step 396, the magnetron is scanned over a second area of the target which corresponds to the second set of predetermined process conditions. In step 396, material from the target is deposited on the substrate. In step 397, steps 393-396 may be optionally repeated until a desired material thickness has been deposited on the substrate.

Although steps 393 and 395 are described as separate from steps 394 and 396, it is contemplated that the adjustment of process conditions can occur as the magnetron enters (and continues to scan through) either the first area or the second area. Thus, it is not necessary for the magnetron or the sputtering process to be halted while the conditions within the chamber are adjusted. Rather, it is contemplated that the conditions may be ramped to the desired setting as the magnetron enters and continues to scan through the corresponding area of the target.

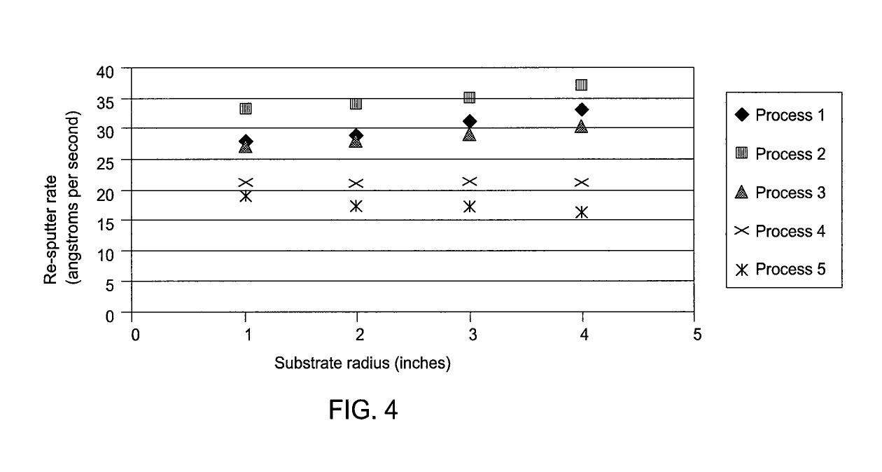

FIG. 4 is chart illustrating the rate of re-sputter across a substrate surface using the scan path of FIG. 2B. For Process 1, a constant bias of 1200 watts was applied to a substrate support during a 20 second PVD process. As can be seen, the rate of re-sputter was greater near the substrate edge through the entire sputtering processing. In Process 2, the magnetron traveled from point A to point B in eight seconds while a substrate support bias of 1200 watts was applied. The magnetron then traveled from point B to point C in four seconds while a substrate support bias of 1600 watts was applied. The magnetron completed the scan path rotation (from point C to point A) in eight seconds while a substrate support bias of 1200 watts was applied.

In Process 3, the magnetron traveled from point A to point B in eight seconds while a substrate support bias of 800 watts was applied. The magnetron then traveled from point B to point C in four seconds while a substrate support bias of 1600 watts was applied. The magnetron completed the scan path rotation (from point C to point A) in eight seconds while a substrate support bias of 800 watts was applied.

In Process 4, the magnetron traveled from point A to point B in eight seconds while a substrate support bias of 400 watts was applied. The magnetron then traveled from point B to point C in four seconds while a substrate support bias of 1600 watts was applied. The magnetron completed the scan path rotation (from point C to point A) in eight seconds while a substrate support bias of 400 watts was applied.

In Process 5, the magnetron traveled from point A to point B in eight seconds while a substrate support bias of 200 watts was applied. The magnetron then traveled from point B to point C in four seconds while a substrate support bias of 1600 watts was applied. The magnetron completed the scan path rotation (from point C to point A) in eight seconds while a substrate support bias of 200 watts was applied. As can be seen in FIG. 4, the optimum processing conditions to reduce re-sputter are those of Process 4.

Although embodiments herein describe synchronizing magnetron position with process conditions to reduce center-to-edge re-sputter rate difference, it is contemplated that the magnetron position and chamber process conditions can be synchronized to reduce other non-uniformities as well. For example, if during a copper deposition process the center of the substrate experiences less bottom coverage than the edge of the substrate, the process conditions within the chamber can be adjusted to account for the bottom coverage non-uniformity. In such an example, the target bias could be increased when the magnetron is near the center of the target in order to increase bottom coverage near the center of the wafer.

Advantages of the present invention include, but are not limited to more uniform processing of substrates during a PVD process. By synchronizing process conditions with the position of the magnetron, center-to-edge deposition differences can be reduced by providing more control over film uniformity. Film uniformity can be improved by compensating for center-to-edge re-sputtering or bottom coverage differences. Thus, layers having more uniform thickness can be deposited, which ultimately allows a higher quality device to be produced.

While the foregoing is directed to embodiments of the present invention, other and further embodiments of the invention may be devised without departing from the basic scope thereof, and the scope thereof is determined by the claims that follow.

We claim:

1. A physical vapor deposition method, comprising:
scanning a magnetron over a first area of a target and sputtering a material from the target to a substrate while biasing the substrate with a first bias; and
scanning the magnetron over a second area of the target and sputtering the material from the target to the substrate while biasing the substrate with a second bias different than the first bias.

2. The method of claim 1, wherein the magnetron is scanned over the first area at a first scanning rate, and the magnetron is scanned over the second area at a second scanning rate different than the first scanning rate.

3. The method of claim 2, wherein the magnetron is scanned in a circular path.

4. The method of claim 3, wherein the second bias is less than half the first bias.

5. The method of claim 1, further comprising scanning the magnetron over a third area of the target and sputtering a material from the target to the substrate while biasing the substrate with a third bias.

6. The method of claim 5, wherein the first bias and the third bias are about equal.

7. The method of claim 6, wherein the second area is positioned between the first area and the third area.

8. The method of claim 7, wherein the first area and the third area are equal in size.

9. The method of claim 7, wherein the first area and the third area are of different sizes.

10. The method of claim 1, wherein first area is surrounded by the second area.

11. The method of claim 1, wherein the target is a unitary piece of material.

12. A physical vapor deposition method, comprising:
scanning a magnetron over a first area of a unitary target and sputtering a material from the unitary target to a substrate under a first set of processing conditions; and
scanning the magnetron over a second area of the unitary target and sputtering the material from the unitary target to the substrate under a second set of processing conditions different than the first set of processing conditions.

13. The method of claim 12, wherein the first set of process conditions and the second set of process conditions include one or more of target bias, electromagnet bias, process gas flow rate, process chamber pressure and substrate temperature.

14. The method of claim 12, wherein the first set of process conditions has a different magnetron scan rate than the second set of process conditions.

15. The method of claim 12, wherein a length of a magnetron scan path within the first area is about equal to a length of a magnetron scan path within the second area.

16. The method of claim 15, wherein the first area and the second area are of different sizes.

17. The method of claim 16, further comprising scanning the magnetron over a third area of the unitary target and sputtering the material from the unitary target to the substrate under a third set of processing conditions different than the first set and the second set of processing conditions.

18. A physical vapor deposition method, comprising:
positioning a substrate adjacent to a target in a processing chamber;
igniting a plasma in a processing region located within the processing chamber;
adjusting processing conditions within the processing chamber to a first set of predetermined processing conditions;
scanning a magnetron over a first area of the target and sputtering material from the target to the substrate;
adjusting the process conditions within the processing chamber to a second set of predetermined processing conditions different than the first set of predetermined processing conditions;
scanning the magnetron over a second area of the target and sputtering material from the target to the substrate;
adjusting the process conditions within the processing chamber to a third set of predetermined processing conditions different than the first set and the second set of predetermined processing conditions; and
scanning the magnetron over a third area of the target and sputtering material from the target to the substrate.

19. The method of claim 18, wherein the first set of predetermined process conditions, the second set of predetermined process conditions, and the third set of predetermined process conditions each have a different substrate support bias.

20. The method of claim 19, wherein the first set of predetermined process conditions, the second set of predetermined process conditions, and the third set of predetermined process conditions each have a different magnetron scan rate.
